(19) United States
(12) Patent Application Publication
(10) Pub. No.: US 2019/0265591 A1
(43) Pub. Date: Aug. 29, 2019

(54) PHOTOSENSITIVE RESIN COMPOSITION AND PHOTOSENSITIVE RESIN PLATE PRECURSOR

(71) Applicant: TORAY INDUSTRIES, INC., Tokyo (JP)

(72) Inventors: Kenji IDO, Okazaki-shi (JP); Yohei NORO, Okazaki-shi (JP); Ryosuke TAKAHASHI, Okazaki-shi (JP)

(73) Assignee: TORAY INDUSTRIES, INC., Tokyo (JP)

(21) Appl. No.: 16/346,019

(22) PCT Filed: Nov. 2, 2017
(86) PCT No.: PCT/JP2017/039802

§ 371 Date: Apr. 29, 2019

(30) Foreign Application Priority Data
Nov. 11, 2016 (JP) 2016-220177

(51) Int. Cl. G03F 7/033; B32B 27/06; G03F 7/031

(52) U.S. Cl. CPC G03F 7/033; G03F 7/031; B32B 27/06

(57) ABSTRACT

The present invention provides a photosensitive resin composition that contains a resin (A) having an ionic functional group, a photopolymerization initiator (B), a photopolymerizable monomer (C), and a fluorine-containing compound (D) having an ionic functional group capable of forming counterions with the resin (A).

By virtue of the present invention, it is possible to economically provide a photosensitive resin letterpress plate capable of maintaining the antifouling plate surface even during a printing step and a post-printing plate washing step without adding operations to the conventional plate making step, thereby providing a plate capable of significantly reducing printing defects caused by dot bridging.

### TECHNICAL FIELD

The present invention relates to photosensitive resin letterpress plate materials. More particularly, it relates to a photosensitive flexographic plate effective for preventing dot bridging during printing.

### BACKGROUND ART

Printing technologies have recently experienced great development, and especially, flexographic printing has a wide variety of applications because print can thereby be applied to any media and this technology is used also for flexible packaging applications and electronics applications including corrugated cardboards, paper cartons and labels. In addition, in consideration of the environment, there has been introduced a water-developable flexographic printing plate, which can be developed with water, in place of conventional treatment involving development using an organic solvent.

In letterpress printing represented by flexographic printing, printing is performed by applying an ink to apexes of a convex relief, press-attaching it with a printing medium, and thereby transferring the ink. Since printing is performed in such a manner, there may take place a phenomenon that the ink applied to relief apexes, especially to apexes of halftone dots, squeezes out to halftone dot slopes or the ink enters concave portions at the time of print pressing. There was a problem that when the ink having squeezed out wet-spreads on a plate surface forming halftone dots, halftone dots are linked by the ink in a region where dot-like print should be applied in a printed matter and, as a result, a print defect called dot bridging is formed. In particular, since flexographic printing inks are lower in viscosity than inks for letterpress printing, the phenomenon of dot bridging tends to occur with the former types of inks. In addition, there was also a secondary problem that the work time for wiping off the wet-spread ink on a printing plate creates opportunity loss, which will cause decrease in productivity.

In order to solve these problems, various methods have been proposed.

In Patent Document 1 and Patent Document 2, there has been proposed a method of applying a fluorine compound onto a letterpress plate by brush application, dipping, spin coating, or the like.

Patent Document 3 provides a water-developable plate containing a hydrophobic compound capable of copolymerizing a polymerizable material containing an element selected from the group consisting of fluorine, chlorine, and silicon with another polymerizable monomer contained in the composition.

In Patent Document 4, there has been proposed a technology in which a nonionic fluorine/silicone material is brought into contact with a plate material, for example by blending in a developer, between an exposure step of forming a relief and a post-exposure step of completing a photocuring reaction, and the ink repellency of a plate surface is imparted and fixed by post-exposure.

### PRIOR ART DOCUMENTS

### Patent Documents

Patent Document 1: Japanese Patent No. 3506797

Patent Document 2: Japanese Patent Laid-open Publication No. 2007-299567

Patent Document 3: Japanese Patent Laid-open Publication No. 6-186740

Patent Document 4: Japanese Patent No. 5731128

### SUMMARY OF THE INVENTION

### Problems to be Solved by the Invention

In Patent Document 1 and Patent Document 2, there is a problem that it is difficult to uniformly apply a liquid material after a plate-making step and the process up to printing including application and drying takes a long time, which causes opportunity loss. In Patent Document 3, since components cannot be well dispersed in the resin to be used in the water-developable plate, the components precipitate from the composition or fogging of the composition takes place due to poor compatibility of the components, and therefore there is a problem that image reproducibility is deteriorated due to scattering of the ultraviolet light required for crosslinking. Patent Document 4 is superior in that anti-staining property can be imparted by the same operation as the conventional plate-making step, but there is a problem of economic disadvantage in considering that the developer containing the materials is disposed in a large quantity as a waste liquid after the completion of plate making.

The present invention has been devised in view of the above-described circumstances, and the present invention provides a photosensitive resin letterpress plate capable of sustaining plate surface anti-staining property even in a printing step or a plate cleaning step after the printing without adding operations to a conventional plate-making step and it is an object of the present invention to provide a plate capable of greatly decreasing printing defects caused by dot bridging.

### Solutions to the Problems

That is, the present invention has the following configurations.

There is provided a photosensitive resin composition comprising (A) a resin having an ionic functional group, (B) a photopolymerization initiator, (C) a photopolymerizable monomer, and (D) a fluorine-containing compound having an ionic functional group capable of forming counterions with the resin (A).

### Effects of the Invention

According to the present invention, plate surface staining caused by wet-spreading of ink between halftone dots during a printing step is prevented and it is possible to continuously provide a satisfactory printed matter having no dot bridging therein. Further, an effect of preventing staining can be obtained at low cost because there is not included any step of bringing a material for preventing plate surface staining into contact after forming halftone dots, such a step being found in other technologies.

### EMBODIMENTS OF THE INVENTION

Embodiments of the present invention will be described below.

The present invention is a photosensitive resin composition comprising (A) a resin having an ionic functional group, (B) a photopolymerization initiator, (C) a photopolymerizable monomer, and (D) a fluorine-containing compound having an ionic functional group capable of forming counterions with the resin (A).

In the present invention, the resin (A) is a resin containing an ionic functional group. As a resin that will serve as a base, it is preferable to use a water-soluble resin from the viewpoint that development using water can be performed in consideration of environmental burden and health damage. Examples of such water-soluble resins include polyvinyl alcohol, polyamide, polyvinylpyrrolidone, polyether and water-soluble polyester, and polyvinyl alcohol is particularly preferable from the viewpoint of solubility in water and ease of processing. Polyvinyl alcohol, which is a water-developable resin, can give variations in solubility depending on the degree of saponification, and in view of difficulty to process as a stock aqueous solution and rigidity of resin itself due to intramolecular hydrogen bonding in complete saponification, polyvinyl alcohol that is at least partially saponified, that is, partially saponified polyvinyl alcohol is preferred. Regarding the degree of saponification, from the viewpoint of water-developability, the degree of saponification is preferably 50 mol % or more and 99 mol % or less, more preferably 60 mol % or more and 90 mol % or less. In a method of measuring a degree of saponification, a 3% aqueous solution of a partially saponified polyvinyl alcohol to be measured is subjected to complete saponification treatment with an excessive amount of 0.5 mol/l aqueous sodium hydroxide solution, then the amount of the sodium hydroxide required for the complete saponification is measured by titration with 0.5 mol/l hydrochloric acid, and the degree of saponification can therefrom be calculated.

Examples of the ionic functional group contained in the resin (A) include a carboxyl group, a sulfonyl group, a quaternary ammonium group, a phosphonium group, a sulfonium group, and derivatives thereof. Such ionic functional groups may be bonded to side chains of the resin or may be constituted as a part of the main chains of the resin. Among such functional groups, a carboxyl group is particularly preferable because of its ease of performing synthesis or modification of resin due to rich variations of reaction. That is, in the present invention, it is preferable that the ionic functional group contained in the resin (A) be a functional group containing a carboxyl group and/or a salt of a carboxylic acid, in other words, the resin (A) be a resin having a functional group modified with a carboxyl group and/or a salt of a carboxylic acid. As a method for introducing such ionic functional groups into the aforementioned polyvinyl alcohol, there is known, for example, the method disclosed in JP-A-11-65115, that is, the method in which a partially saponified polyvinyl acetate is reacted with an acid anhydride, thereby introducing carboxyl groups into polymer side chains from the hydroxyl groups of the partially saponified polyvinyl acetate as starting points. In such a reaction, the amount of the carboxyl groups can be easily adjusted by changing the charging ratio of the acid anhydride or the processing time.

The photosensitive resin composition of the present invention includes (D) a fluorine-containing compound having an ionic functional group capable of forming counterions with the resin (A). By forming a counterion with an ion formed in the resin (A), the fluorine compound is fixed in the photosensitive resin composition by electrostatic interaction, so that an anti-staining property can be maintained. Specifically, a fluorine compound having a cationic functional group such as a quaternary ammonium group, a phosphonium group, or a sulfonium group is used if the ions contained in the resin exhibit an anionic property like a carboxyl group. On the other hand, if the ion contained in the resin is cationic, a fluorine compound having an anionic functional group such as a sulfonyl group or a carboxyl group is used. In the case of introducing a carboxyl group, which is easily adjustable as the resin (A) as described above, a quaternary ammonium group, which is industrially most versatile and can be prepared at low cost, is a particularly preferable combination. That is, in the present invention, it is preferable that the fluorine compound (D) have a functional group containing a quaternary ammonium ion, in other words, a functional group containing a quaternary ammonium group capable of generating a quaternary ammonium ion.

Such an ionic fluorine compound is particularly preferably a single molecule. The “single molecule” is a compound that does not contain repeating units of the same type of monomer. When the fluorine compound is a polymeric compound such as an oligomer or a polymer, some restriction is imposed on the movement of a long molecular chain, so that surfactancy action is weakened because the fluorine compound hardly aligns on the later plate surface. Some of such fluorine compounds are commercially available; examples of cationic products include “FTERGENT” (registered trademark) 300, “FTERGENT” 310 and “FTERGENT” 320 (manufactured by NEOS Co., Ltd.), which each contain a quaternary ammonium group, and examples of anionic products include “FTERGENT” 100, 110 and 150 (trade names; manufactured by NEOS Co., Ltd.), which each contain a salt of sulfonic acid. From the viewpoint of the amount necessary for developing the antifouling effect and the deterioration in workability due to foaming, the addition amount of such a fluorine compound is preferably 0.3 parts by weight or more and 5.0 parts by weight or less, and more preferably 0.3 parts by weight or more and 3.0 parts by weight or less, based on 100 parts by weight of the total amount of the photosensitive resin solids.

In the present invention, any substance capable of making polymerizable carbon-carbon unsaturated groups start polymerization by light can be used as the photopolymerization initiator (B). Among them, those having a function of generating radicals by self-decomposition or hydrogen extraction due to light absorption are preferably used. Examples thereof include benzoin alkyl ethers, benzophenones, anthraquinones, benzils, acetophenones, and diacetyls. In order that the photocuring reaction proceeds sufficiently at the time of exposure to light and unexposed areas are not excessively influenced by the scattered light from the exposed portion, the load of the photopolymerization initiator is preferably within the range of 0.1 to 20 parts by weight, more preferably 0.5 to 10 parts by weight based on 100 parts by weight of the total solid components of the photosensitive resin composition.

In the present invention, the photopolymerizable monomer (C) is a monomer having a carbon-carbon unsaturated group whose polymerization reaction is initiated by light. Specific examples thereof include the followings, but the invention is not limited thereto. Said specific examples include 2-hydroxy-3-acryloyloxypropyl methacrylate, a reaction product of 2-acryloyloxyethylsuccinic acid and glycidyl methacrylate, a reaction product of 2-acryloyloxyethyl-2-hydroxyethyl-phthalic acid and methacrylic acid, a reaction product of 2-hydroxyethyl acrylate and methacrylic acid, a reaction product of ethylene glycol diglycidyl ether, acrylic acid and methacrylic acid, polyethylene glycol monomethacrylate, and polyethylene glycol dimethacrylate. The load of the photopolymerizable monomer (C) is preferably 1 part by weight or more and 50 parts by weight or less, more preferably 1 part by weight or more and 30 parts by weight or less based on 100 parts by weight of the solid components of the photosensitive resin composition. By adopting such a load, photosensitivity is imparted to the resin composition, so that it is possible to obtain an appropriate hardness as a printing plate after photocuring.

For the reason of ease in preparing individual materials, the photosensitive resin composition of the present invention is particularly preferably one containing both a polyvinyl alcohol having a carboxyl group and/or a functional group modified with a carboxylic acid salt as the resin (A) and a fluorine-containing compound having functional groups including a quaternary ammonium group as the fluorine-containing compound (D).

It is also possible to add polyhydric alcohols such as ethylene glycol, diethylene glycol, triethylene glycol, glycerin and derivatives thereof, trimethylolpropane and derivatives thereof, trimethylolethane and derivatives thereof, and pentaerythritol and derivatives thereof to the photosensitive resin composition of the present invention as a compatibilization aid for enhancing compatibility and flexibility. Such polyhydric alcohols preferably account for 60 parts by weight or less based on the whole photosensitive resin composition.

In order to improve the thermal stability of the photosensitive resin composition of the present invention, a conventionally known polymerization inhibitor may be added. Examples of a preferable polymerization inhibitor include phenols, hydroquinones, catechols, and hydroxyamine derivatives. The load of these agents to be used may be within the range of 0.001 to 5 parts by weight based on the whole photosensitive resin composition.

In addition, other components such as dyes, pigments, surfactants, defoaming agents, ultraviolet absorbers, and flavoring agents may be added as required.

Next, the photosensitive resin plate precursor of the present invention will be described.

Generally, printing plate precursors have a configuration in which a photosensitive resin layer is laminated on a dimensionally stable support. By laminating the photosensitive resin composition described in the present invention on a support and experiencing the steps of exposure, development and drying, the resultant can be used as a relief layer with irregularities formed like an image and can be used as a printing plate for various types of printing.

As a dimensionally stable support, sheets of plastics, such as polyester, or plates of metals, such as steel, stainless steel and aluminum, can be used. Although the thickness of the support is not particularly limited, it is preferably in the range of 100 to 350 μm from the viewpoint of handleability and flexibility. A thickness of 100 μm or more leads to improved handleability as a support, and a thickness of 350 μm or less leads to improved flexibility as a printing plate precursor. In addition, for the purpose of improving the adhesion between the support and the photosensitive resin layer, the support has preferably been subjected to adhesion-promoting treatment. Examples of the method of the adhesion-promoting treatment include mechanical treatments such as sandblasting, physical treatments such as corona discharge, and chemical treatments by coating, etc.; from the viewpoint of adhesion, it is preferable to provide an adhesion-promoting layer by coating.

The photosensitive resin layer is formed from the photosensitive resin composition of the present invention. The thickness of the photosensitive resin layer is preferably 0.3 mm or more, more preferably 0.5 mm or more, from the viewpoint of having a sufficient relief depth and improving printability. On the other hand, the thickness is preferably 5 mm or less, more preferably 3 mm or less, from the viewpoint of making the active ray used for exposure sufficiently reach the bottom portion and thereby further improving image reproducibility.

The photosensitive resin plate precursor of the present invention preferably has a cover film on the photosensitive resin layer from the viewpoint of surface protection and prevention of adhesion of foreign matters or the like. The photosensitive resin layer may be in direct contact with the cover film or may have one layer or a plurality of layers between the photosensitive resin layer and the cover film. Examples of the layer between the photosensitive resin layer and the cover film include an anti-adhesion layer provided for the purpose of preventing adhesion of the surface of the photosensitive resin layer.

Although the material of the cover film is not particularly limited, sheets of plastics such as polyester and polyethylene are preferably used. Although the thickness of the cover film is not particularly limited, the range of 10 to 150 μm is preferable from the viewpoint of handleability and cost. The surface of the cover film may have been roughened for the purpose of improving its adhesion with an original image film.

The photosensitive resin plate precursor of the present invention may further comprise a heat-sensitive mask layer on the photosensitive resin layer. The heat-sensitive mask layer is preferably a layer which substantially shields ultraviolet light and absorbs infrared laser light during drawing, and partially or entirely sublimates or ablates instantaneously by heat generated due to the absorption of the light. This generates a difference in optical density between the laser-irradiated part and the non-irradiated part, allowing the heat-sensitive mask layer to function in the same manner as conventional original image films.

Next, methods for the production of the photosensitive resin composition of the present invention and for the production of a photosensitive resin plate precursor using the photosensitive resin composition will be described, but the present invention is not limited thereto.

After heat-dissolving the resin (A) having an ionic functional group in a water/alcohol mixed solvent, a compound of the photopolymerization initiator (B), the photopolymerizable monomer (C), the fluorine-containing compound (D) having an ionic functional group capable of forming counterions and, as required, a plasticizer and other additive(s) are added, and the resultant is fully mixed by stirring to obtain a photosensitive resin composition solution.

The resultant photosensitive resin composition solution is cast on a support optionally having an adhesion-promoting layer and then is dried to form a photosensitive resin layer made of the photosensitive resin composition. Then, by tightly adhering a cover film optionally coated with an anti-adhesion layer onto the photosensitive resin layer, a photosensitive resin plate precursor can be obtained. Alternatively, such a photosensitive resin plate precursor can be obtained also by preparing a photosensitive resin sheet by dry film formation and then laminating a support and a cover film in such a manner that the photosensitive resin sheet is sandwiched therebetween.

By using the above-described photosensitive resin plate precursor, a letterpress printing plate can be obtained.

As a plate-making method, conventionally known methods can be used.

When the photosensitive resin plate precursor includes no heat-sensitive mask layer (hereinafter referred to as an “analog plate”) but includes a cover film, a negative or positive original image film is tightly adhered onto the photosensitive resin layer after peeling off the cover film, and then the original image film is irradiated with ultraviolet light to photocure the photosensitive resin layer. When the photosensitive resin plate precursor includes a heat-sensitive mask layer (hereinafter referred to as a CTP plate), after peeling off the cover film an image corresponding to an original image film is drawn using a laser imaging device and the thus drawn image is subsequently irradiated with ultraviolet light to photocure the photosensitive resin layer. The ultraviolet irradiation is usually carried out using a high-pressure mercury lamp, an ultrahigh-pressure mercury lamp, a metal halide lamp, a xenon lamp, a carbon arc lamp, a chemical lamp, or the like, which can emit light having a wavelength of 300 to 400 nm. Particularly, when the reproducibility of fine lines and dots is required, it is also possible to perform exposure from the side where the support is located (back exposure) for a short time before peeling off the cover film.

Then, the photosensitive resin plate precursor is immersed in a developer solution and a relief image is formed on a substrate using a brush-type developing device, which removes uncured parts by rubbing with a brush. As an alternative to the brush-type developing device, a spray-type developing device can also be used. The liquid temperature during the development is preferably 15 to 40° C. After formation of a relief image, the resulting plate precursor is dried at 50 to 70° C. for about 10 minutes and is optionally treated with activate light in the air or vacuum, and a photosensitive resin plate can thereby be obtained.

The method for producing a printed matter of the present invention can be a production method including the step of applying a flexographic printing ink to the above-described letterpress printing plate. Examples of the flexographic printing ink include PHA (manufactured by T&K TOKA Corporation), “FLASH DRY” (registered trademark, manufactured by Toyo Ink Co., Ltd.) and “UVAFLEX” (registered trademark) Y77 (manufactured by Zeller+Gmelin), which are commercially available. The composition of such flexographic printing inks includes, for example, a pigment, a resin such as acrylic oligomer, an acrylate monomer, and a polymerization initiator. According to the method for producing a printed matter of the present invention, plate surface staining caused by wet-spreading of ink between halftone dots is prevented and it is possible to continuously provide a satisfactory printed matter having no dot bridging therein. Further, an effect of preventing staining can be obtained at low cost because there is not included any step of bringing a material for preventing plate surface staining into contact after forming halftone dots, such a step being found in other technologies.

The photosensitive resin composition of the present invention is most suitably used for letterpress printing, especially for flexographic printing, and it can also be used for planographic printing, intaglio printing, and stencil printing, and as a photoresist.

### EXAMPLES

Hereafter, the present invention will be described in detail by examples.

### Synthesis Example of Resin (A) Containing Ionic Functional Group

Partially saponified polyvinyl alcohol “GOHSENOL” (registered trademark) “KL-05” (degree of saponification: 78.5 to 82.0 mol %) manufactured by The Nippon Synthetic Chemical Industry Co., Ltd. was swollen in acetone, followed by the addition of 1.0 mol % of succinic anhydride and stirring at 60° C. for 6 hours, and thus carboxyl groups were added to the molecular chain. The resulting polymer was washed with acetone to remove unreacted succinic anhydride and was dried. The acid value of the polymer was measured and found to be 10.0 mg KOH/g. The resin obtained by this operation is hereinafter referred to as “Resin 1”.

[Preparation of Support Having Adhesion-Promoting Layer]

A mixture of 260 parts by weight of “VYLON” (registered trademark) 31SS (toluene solution of saturated polyester resin, manufactured by Toyobo Co., Ltd.) and 2 parts by weight of “PS-8A” (benzoin ethyl ether, manufactured by Wako Pure Chemical Industries, Ltd.) was heated at 70° C. for 2 hours and then cooled to 30° C. and 7 parts by weight of ethylene glycol diglycidyl ether dimethacrylate was added and mixed for 2 hours. Further, 25 parts by weight of “Coronate” (registered trademark) 3015E (ethyl acetate solution of polyvalent isocyanate resin, manufactured by Tosoh Corporation) and 14 parts by weight of “EC-1368” (industrial adhesive, manufactured by Sumitomo 3M Limited) were added and mixed to obtain Coating Liquid 1 for an adhesion-promoting layer.

First, 50 parts by weight of “GOHSENOL” (registered trademark) KH-17 (polyvinyl alcohol having a degree of saponification of 78.5 to 81.5 mol %, manufactured by The Nippon Synthetic Chemical Industry Co., Ltd.) was mixed in a mixed solvent of 200 parts by weight of “SOLMIX” (registered trademark) H-11, (alcohol mixture, manufactured by Japan Alcohol Trading Co., Ltd.) and 200 parts by weight of water at 70° C. for 2 hours and then 1.5 parts by weight of “Blemmer” (registered trademark) G (glycidyl methacrylate, manufactured by NOF Corporation) was added and mixed for 1 hour. Further, 3 parts by weight of a copolymer having a (dimethylaminoethyl methacrylate)/(2-hydroxyethyl methacrylate) weight ratio of 2/1 (manufactured by Kyoeisha Chemical Co., Ltd.), 5 parts by weight of “Irgacure” (registered trademark) 651 (benzyl methyl ketal, manufactured by BASF), 21 parts by weight of “Epoxy Ester 70PA” (acrylic acid adduct of propylene glycol diglycidyl ether, manufactured by Kyoeisha Chemical Co., Ltd.), and 20 parts by weight of ethylene glycol diglycidyl ether dimethacrylate were added, mixed for 90 minutes, and then cooled to 50° C. Then, 0.1 parts by weight of “MEGAFACE” (registered trademark) F-556 (manufactured by DIC Corporation) was added and mixed for 30 minutes to obtain Coating Liquid 2 for an adhesion-promoting layer.

The Coating Liquid 1 for an easy adhesion layer was applied to a “Lumirror” (registered trademark) T60 (polyester film, manufactured by Toray Industries, Inc.) having a thickness of 125 μm with a bar coater so as to have a thickness of 40 μm and was heated in an oven at 180° C. for 3 minutes to remove the solvent, and then the Coating Liquid 2 for an easy adhesion layer was applied thereon with a bar coater so as to have a dry film thickness of 30 μm and was heated in an oven at 160° C. for 3 minutes to obtain a support having an adhesion-promoting layer.

### [Production of Cover Film for Analog Plate]

“GOHSENOL” AL-06 (partially saponified polyvinyl alcohol having a degree of saponification of 91 to 94 mol %, manufactured by The Nippon Synthetic Chemical Industry Co., Ltd.) was applied to “Lumirror” S10 having a thickness of 100 μm and roughened to a surface roughness Ra of 0.1 to 0.6 μm (polyester film, manufactured by Toray Industries, Inc.) so as to have a dry film thickness of 1 μm and was dried at 100° C. for 25 seconds to obtain Cover Film (I-1) for an analog plate.

### [Plate-Making Method]

Plate making was carried out as follows using a batch type exposure developing machine “TOMIFLEX” (manufactured by TOMIHIRO-SANGYO Co., Ltd.). The cover film of the obtained photosensitive resin plate precursor was peeled off and a negative film was placed in vacuum contact with the peeled surface using a vinyl chloride film, followed by exposure to light to a cumulative light amount of about 16,000 mJ/cm², and then the resultant was developed for 60 seconds with tap water with a temperature adjusted to 25° C. Thereafter, the resultant was dried in an oven at 60° C. for 10 minutes to obtain a photosensitive resin plate.

### [Evaluation Method]

The evaluations in each Example and Comparative Example were carried out by the following methods.

### (1) Measurement of Contact Angle

The degree of ease of wet spreading of an ink on a plate surface was evaluated using the contact angle to the ink. To a solid print portion of the plate surface was dropped 1 μL of a flexographic ink (“UV Flexo Red PHA-L03” (manufactured by T&K TOKA Corporation) at room temperature, and the contact angle at 50 seconds after the dropping was measured with a contact angle meter “DMe-201” (manufactured by Kyowa Interface Science Co., Ltd.), and this was taken as the contact angle with respect to the ink. Since the smaller the contact angle with respect to an ink, the greater the wet-spreading of the ink between halftone dots on the plate surface, which will cause dot bridging, higher values of the contact angle value with respect to the ink are preferred. In the present examples, it was judged preferable when the contact angle with respect to the ink was 40° or more, and more preferable when the contact angle was 42° or more.

### (2) Actual Printing Evaluation

From the viewpoint that the cause of dot bridging is an ink that has wet spread on a plate surface, evaluation using an ink deposition area ratio on a plate surface as an alternative index was performed under the following conditions as evaluation using an actual printing machine.

Print was applied to art paper at a speed of 60 m/min by using a flexographic printing machine equipped with a 1000 LPI anilox roll using “UV Flexo Red PHA-L03” (manufactured by T&K TOKA Corporation) as the ink. As a cushion tape for bringing the plate into close contact with a plate cylinder, “tesa Softprint” (registered trademark) 52017 (manufactured by tesa) having a thickness of 0.38 μm was used. As the photosensitive resin plate to be evaluated, one on which an image with a 150 LPI halftone dot density of 30% had been formed was used, and after 10,000 m printing, evaluation was carried out based on the ink deposition area ratio, namely, the ratio of the area of the regions on which the ink deposited to the total area of the concave portions located between printing halftone dots. The case that no ink deposited was rated as 5, the case that the ink deposition area ratio was 30% or less was rated as 3, the case that the ink deposition area ratio was more than 30% was rated as 1, and the rate 5 was judged as passed.

### Example 1

Into a three-necked flask equipped with a stirring spatula and a cooling tube, 40 parts by weight of resin 1 as the resin (A) component containing an ionic functional group, 1.3 parts by weight of benzyl dimethyl ketal as the photopolymerization initiator (B) component, and 30 parts by weight of trimethylolpropane as a plasticizer were added and a mixed solvent of 50 parts by weight of “SOLMIX” (registered trademark) H-11 (alcohol mixture, manufactured by Japan Alcohol Trading Co., Ltd.) and 50 parts by weight of water was mixed and then heated at 80° C. for 2 hours with stirring, and thus the components (A) and (B) were dissolved. After cooling to 70° C., 8.0 parts by weight of glycidyl methacrylate as the photopolymerizable monomer (C) component, 10 parts by weight of polyethylene glycol monomethacrylate (“Blemmer” (registered trademark) AE400/manufactured by NOF Corporation), 10 parts by weight of polyethylene glycol dimethacrylate (“Blemmer” AD400/manufactured by NOF Corporation) were added, and the resin (A), a fluorine-containing quaternary ammonium salt compound “FTERGENT 320” (manufactured by NEOS Co., Ltd.) as the fluorine-containing compound (D) component having an ionic functional group capable of forming counterions with resin (A), and other components were added and stirred for 30 minutes to obtain a composition solution 1 for a photosensitive resin composition 1.

The contents of the constituents (A), (B), (C) and (D) are shown in Tables 1 and 2.

TABLE 1

| | | parts by |
|---|---|---|
| | Composition | weight |
| Component (A) | Resin 1 | 40 |
| Component (B) | Benzyl dimethyl ketal | 1.3 |
| Component (C) | Glycidyl methacrylate | 8 |
| | Polyethylene glycol | 10 |
| | monomethacrylate | |
| | Polyethylene glycol | 10 |
| | dimethacrylate | |
| Plasticizer | Trimethylolpropane | 30 |
| UV absorber | 2-(2′-Hydroxy-3′-t- | 0.04 |
| | butyl-5′-methylphenyl)- | |
| | 5-chlorobenzotriazole | |
| Component (D) | (shown in Table 2) | (shown in |
| | | Table 2) |

TABLE 2

| | | | | | | | Evaluation | |
|---|---|---|---|---|---|---|---|---|
| | | | | | | | Contact | |
| | | | Component (D) | | | | angle with | Ink |
| | Component (A) | | | | | parts by | respect | deposition |
| | Material | Ionicity | Name of material | Ionicity | Form | weight | to ink | evaluation |
| Example 1 | Resin 1 | Anion | FTERGENT 320 | Cation | Single | 0.5 | 51° | 5 |
| | | | | | molecule | | | |
| Example 2 | Resin 1 | Anion | FTERGENT 310 | Cation | Single | 0.5 | 40° | 5 |
| | | | | | molecule | | | |
| Example 3 | Resin 1 | Anion | ETERGENT 300 | Cation | Single | 0.5 | 42° | 5 |
| | | | | | molecule | | | |
| Comparative | KL-05 | Nonion | ETERGENT 300 | Cation | Single | 0.5 | 36° | 1 |
| Example 1 | | | | | molecule | | | |
| Comparative | Resin 1 | Anion | (No addition) | — | — | 0 | 20° | 1 |
| Example 2 | | | | | | | | |
| Comparative | Resin 1 | Anion | FTERGENT 100 | Anion | Single | 0.5 | 37° | 3 |
| Example 3 | | | | | molecule | | | |
| Comparative | Resin 1 | Anion | FTERGENT 251 | Nonion | Single | 0.5 | 22° | 1 |
| Example 4 | | | | | molecule | | | |
| Comparative | Resin 1 | Anion | FAEP-6 | Nonion | Single | 1.0 | 22° | 1 |
| Example 5 | | | | | molecule | | | |
| Comparative | Resin 1 | Anion | LE-605 | Nonion | Polymer | 1.0 | 17° | 1 |
| Example 6 | | | | | | | | |

The photosensitive resin composition solution 1 obtained was cast on the support having an adhesion-promoting layer and then dried at 60° C. for 2.5 hours. At this time, the post-drying thickness of the plate (polyester film+photosensitive resin layer) was controlled to be 1.14 mm. Onto the thus-obtained photosensitive resin layer was applied a mixed solvent (water/ethanol=50/50 (weight ratio)) was applied, and the cover film for the analog plate was press-adhered to the surface to obtain a photosensitive resin plate precursor. A printing plate was produced by the method described above using the photosensitive resin plate precursor obtained, and then the properties of the printing plate were evaluated and the results are shown in Table 2. The contact angle with respect to the ink was as high as 51° and the ink deposition area ratio of the printing plate surface in printing was rated as 5. Moreover, no ink entanglement was found.

### Example 2

A photosensitive resin layer and a photosensitive resin plate precursor were prepared in the same manner as in Example 1 except that the component (D) of the photosensitive resin composition was changed to a fluorine-containing quaternary ammonium salt compound “FTERGENT 310” (manufactured by NEOS Co., Ltd.). The evaluation results are shown in Table 2. The ink deposition area ratio was rated as 5.

### Example 3

A photosensitive resin layer and a photosensitive resin plate precursor were prepared in the same manner as in Example 1 except that the component (D) of the photosensitive resin composition was changed to a fluorine-containing quaternary ammonium salt compound “FTERGENT 300” (manufactured by NEOS Co., Ltd.). The ink deposition area ratio was rated as 5.

### Comparative Example 1

A photosensitive resin layer and a photosensitive resin plate precursor were prepared in the same manner as in Example 1 except that the component (A) of the photosensitive resin composition was changed to a nonionic partially saponified polyvinyl alcohol not having been modified with a carboxylic acid “KL-05” (degree of saponification: 78.5 to 82.0 mol %, manufactured by The Nippon Synthetic Chemical Industry Co., Ltd.). The contact angle with respect to ink was smaller than 40°, and the score of the ink deposition area ratio was rated as 1.

### Comparative Example 2

A photosensitive resin layer and a photosensitive resin plate precursor were prepared in the same manner as in Example 1 except that the component (D) of the photosensitive resin composition was not added. The ink deposition area ratio was rated as 1.

### Comparative Example 3

A photosensitive resin layer and a photosensitive resin plate precursor were prepared in the same manner as in Example 1 except that the component (D) of the photosensitive resin composition was changed to a fluorine-containing sulfonic acid salt compound “FTERGENT 100” (manufactured by Neos Co., Ltd.) whereas the component (A) was anionic. When the components (A) and (D) were of a combination with the same Tonicity, the ink deposition area ratio was rated as 3, which was rejected.

### Comparative Example 4

A photosensitive resin layer and a photosensitive resin plate precursor were prepared in the same manner as in Example 1 except that the component (D) of the photosensitive resin composition was changed to a nonionic ethylene oxide unit-containing fluorine-based surfactant “FTERGENT 251” (manufactured by NEOS Co., Ltd.) whereas the component (A) was anionic. When the component (D) was nonionic, there was not observed an effect of maintaining ink repellency and the contact angle with respect to ink was low. Likewise, the ink deposition area ratio was rated as 1.

### Comparative Example 5

A photosensitive resin layer and a photosensitive resin plate precursor were prepared in the same manner as in Example 1 except that the component (D) of the photosensitive resin composition was changed to a nonionic terminal epoxy-modified containing fluorine-based compound, 3-(perfluorohexyl)propene-1,2-oxide, “FAEP-6” (manufactured by UNIMATEC Co., Ltd.) whereas the component (A) was anionic. Even though the component (D) was terminated with epoxy, which is a reactive group, the ink-repelling effect was not maintained and the ink deposition area ratio was rated as 1.

### Comparative Example 6

A photosensitive resin layer and a photosensitive resin plate precursor were prepared in the same manner as in Example 1 except that the component (D) of the photosensitive resin composition was changed to a nonionic polymer fluorine-based compound “LE-605” (manufactured by Kyoeisha Chemical Co., Ltd.) whereas the component (A) was anionic. The value of the contact angle with respect to ink was low and the ink-repelling effect was not observed. In addition, the ink deposition area ratio was rated as 1.

1. A photosensitive resin composition comprising (A) a resin having an ionic functional group, (B) a photopolymerization initiator, (C) a photopolymerizable monomer, and (D) a fluorine-containing compound having an ionic functional group capable of forming counterions with the resin (A).

2. The photosensitive resin composition according to claim 1, wherein the resin (A) is a polyvinyl alcohol at least part of which has been saponified and contains an ionic functional group.

3. The photosensitive resin composition according to claim 1, wherein the ionic functional group contained in the resin (A) is a functional group containing a carboxyl group and/or a salt of a carboxylic acid.

4. The photosensitive resin composition according to claim 1, wherein the ionic functional group contained in the fluorine compound (D) is a functional group containing a quaternary ammonium group.

5. The photosensitive resin composition according to claim 1, wherein the fluorine compound (D) is a single molecule.

6. A photosensitive resin plate precursor produced using the photosensitive resin composition according to claim 1.

7. A letterpress printing plate produced using the photosensitive resin plate precursor according to claim 6.

8. A method for producing a printed matter comprising the step of applying a flexographic printing ink to the letterpress printing plate according to claim 7.

9. The photosensitive resin composition according to claim 2, wherein the ionic functional group contained in the resin (A) is a functional group containing a carboxyl group and/or a salt of a carboxylic acid.

10. The photosensitive resin composition according to claim 2, wherein the ionic functional group contained in the fluorine compound (D) is a functional group containing a quaternary ammonium group.

11. The photosensitive resin composition according to claim 3, wherein the ionic functional group contained in the fluorine compound (D) is a functional group containing a quaternary ammonium group.

12. The photosensitive resin composition according to claim 2, wherein the fluorine compound (D) is a single molecule.

13. The photosensitive resin composition according to claim 3, wherein the fluorine compound (D) is a single molecule.

14. The photosensitive resin composition according to claim 4, wherein the fluorine compound (D) is a single molecule.

15. A photosensitive resin plate precursor produced using the photosensitive resin composition according to claim 2.

16. A photosensitive resin plate precursor produced using the photosensitive resin composition according to claim 3.

17. A photosensitive resin plate precursor produced using the photosensitive resin composition according to claim 4.

18. A photosensitive resin plate precursor produced using the photosensitive resin composition according to claim 5.
